(19) United States
(12) Patent Application Publication
(10) Pub. No.: US 2026/0293755 A1
(43) Pub. Date: Sep. 24, 2026

(54) SEMICONDUCTOR MODULE AND METHOD FOR MANUFACTURING SEMICONDUCTOR MODULE

(71) Applicants: Kabushiki Kaisha Toshiba, Kawasaki-shi (JP); Toshiba Electronic Devices & Storage Corporation, Kawasaki-shi (JP)

(72) Inventors: Nobuaki MAKINO, Fujisawa Kanagawa (JP); Satoshi AKUTSU, Yokohama Kanagawa (JP); Takuma SUZUKI, Himeji Hyogo (JP)

(21) Appl. No.: 19/398,974

(22) Filed: Nov. 24, 2025

(30) Foreign Application Priority Data
Mar. 21, 2025 (JP) 2025-046987

(51) Int. Cl. H10W 74/47; H10W 74/01; H10W 74/10; H10W 72/00; H10W 90/00

(52) U.S. Cl. CPC H10W 74/476; H10W 74/01; H10W 74/121; H10W 72/884; H10W 90/736; H10W 90/756

(57) ABSTRACT

A semiconductor module according to an embodiment includes a semiconductor element, an electrode, and a sealing member. The electrode is electrically connected to the semiconductor element. The sealing member covers at least a portion of the electrode. The sealing member includes a SiN layer and a silicone gel layer. The SiN layer includes a Si-N-Si bond. The silicone gel layer includes a silicone gel.

### CROSS-REFERENCE TO RELATED APPLICATIONS

This application is based upon and claims the benefit of priority from Japanese Patent Application No. 2025-046987, filed on Mar. 21, 2025; the entire contents of which are incorporated herein by reference.

### FIELD

Embodiments described herein relate generally to a semiconductor module and a method for manufacturing a semiconductor module.

### BACKGROUND

Semiconductor modules are known in which a sealing member is located on an electrode located on a semiconductor element. Such a semiconductor module is problematic in that, when the sealing member includes a silicone gel, moisture that penetrates the sealing member may easily reach the electrode and cause failure.

### BRIEF DESCRIPTION OF THE DRAWINGS

FIG. 1 is a cross-sectional view schematically showing a semiconductor module according to a first embodiment;

FIG. 2 is a cross-sectional view schematically showing a portion of the semiconductor module according to the first embodiment;

FIG. 3 is a cross-sectional view schematically showing a portion of the semiconductor module according to the first embodiment;

FIG. 4 is a cross-sectional view schematically showing a portion of a semiconductor module according to a second embodiment;

FIG. 5 is a cross-sectional view schematically showing a portion of a semiconductor module according to a third embodiment;

FIGS. 6A to 6E are cross-sectional views schematically showing a method for manufacturing the semiconductor module according to the first embodiment;

FIGS. 7A to 7D are cross-sectional views schematically showing a modification of the method for manufacturing the semiconductor module according to the first embodiment;

FIGS. 8A to 8E are cross-sectional views schematically showing a method for manufacturing the semiconductor module according to the second embodiment;

FIGS. 9A to 9E are cross-sectional views schematically showing a modification of the method for manufacturing the semiconductor module according to the second embodiment;

FIGS. 10A to 10D are cross-sectional views schematically showing a method for manufacturing the semiconductor module according to the third embodiment; and

FIGS. 11A to 11D are cross-sectional views schematically showing a modification of the method for manufacturing the semiconductor module according to the third embodiment.

### DETAILED DESCRIPTION

A semiconductor module according to an embodiment includes a semiconductor element, an electrode, and a sealing member. The electrode is electrically connected to the semiconductor element. The sealing member covers at least a portion of the electrode. The sealing member includes a SiN layer and a silicone gel layer. The SiN layer includes a Si-N-Si bond. The silicone gel layer includes a silicone gel.

Hereinafter, embodiments of the invention will be described with reference to the drawings.

The drawings are schematic or conceptual, and the relationship between the thickness and width of each portion, the proportions of sizes among portions, and the like are not necessarily the same as the actual values. Even the dimensions and proportion of the same portion may be illustrated differently depending on the drawing.

In the specification and drawings, components similar to those described in regard to a drawing thereinabove are marked with like reference numerals, and a detailed description is omitted as appropriate.

### Semiconductor module

### First embodiment

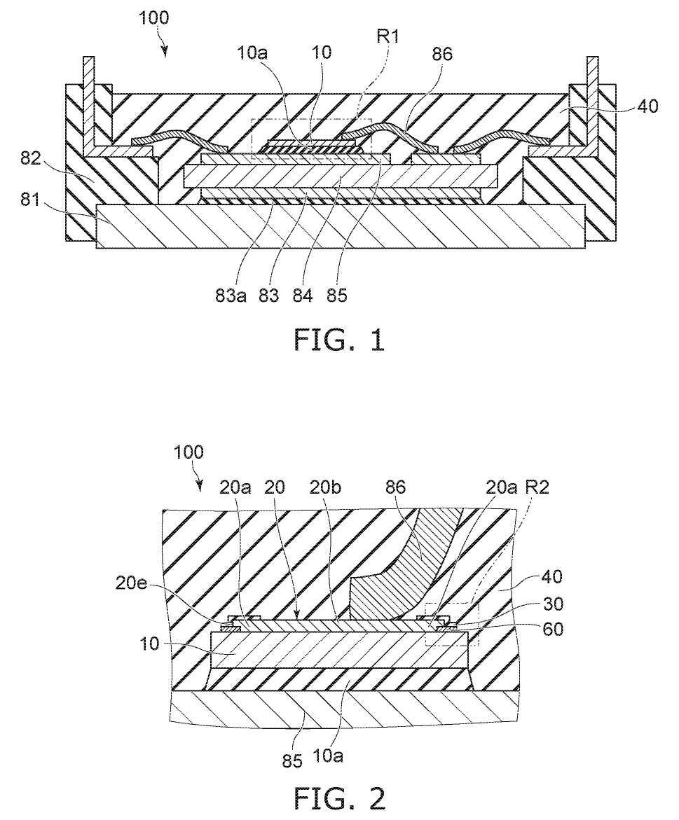

FIG. 1 is a cross-sectional view schematically showing a semiconductor module according to a first embodiment.

FIG. 2 is a cross-sectional view schematically showing a portion of the semiconductor module according to the first embodiment.

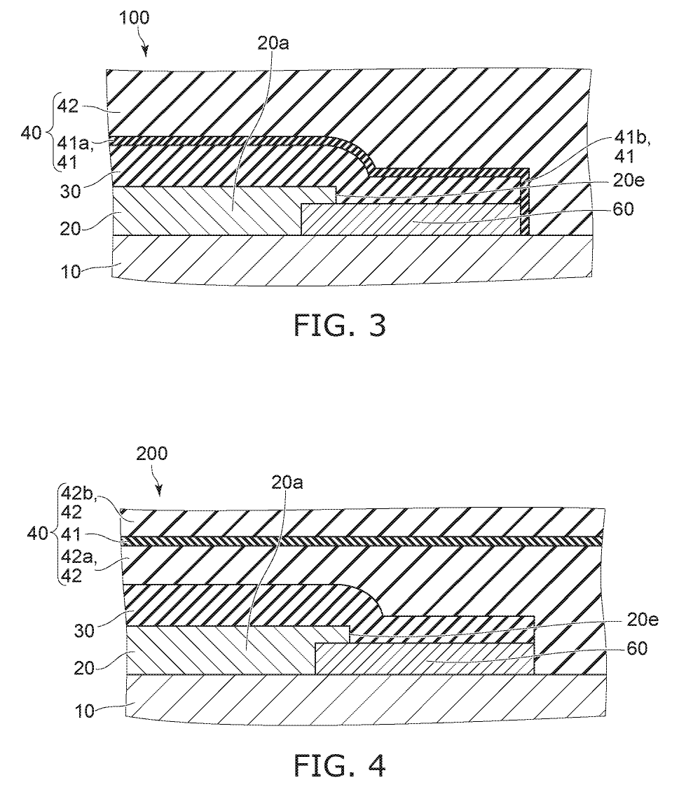

FIG. 3 is a cross-sectional view schematically showing a portion of the semiconductor module according to the first embodiment.

FIG. 2 is an enlarged view of region R1 shown in FIG. 1.

FIG. 3 is an enlarged view of region R2 shown in FIG. 2.

As shown in FIGS. 1 to 3, the semiconductor module 100 according to the first embodiment includes a semiconductor element 10, an electrode 20, a protective film 30, a sealing member 40, a base plate 81, a frame 82, a first member 83, a second member 84, a third member 85, and a wire 86.

In the following description, the direction from the semiconductor element 10 toward the electrode 20 is referred to as "up", and the direction from the electrode 20 toward the semiconductor element 10 is referred to as "down". Directions orthogonal to the vertical direction are referred to as the "side". For example, "at the side" means "arranged in any direction orthogonal to the vertical direction".

The base plate 81 is positioned at the lower part of the semiconductor module 100. The frame 82 extends upward to surround the outer perimeter of the base plate 81. The first member 83, the second member 84, and the third member 85 are located on the base plate 81 inside a space surrounded with the frame 82. The first member 83, the second member 84, and the third member 85 cover at least a portion of the upper surface of the base plate 81. The first member 83 is located on the base plate 81 with a first adhesive 83a interposed. The first member 83 covers at least a portion of the upper surface of the base plate 81. The second member 84 is located on the first member 83. The second member 84 covers at least a portion of the upper surface of the first member 83. The third member 85 is located on the second member 84. The third member 85 covers at least a portion of the upper surface of the second member 84. The semiconductor element 10 is located on the third member 85 with a second adhesive 10a interposed. The semiconductor element 10 covers at least a portion of the upper surface of the third member 85. The base plate 81, the frame 82, the first member 83, the second member 84, and the third member 85 may be provided as necessary, and are omissible.

The base plate 81 includes, for example, at least one of aluminum, silicon carbide, or copper. The frame 82 includes, for example, at least one of polyamide or PPS (polyphenylene sulfide). The first member 83 includes, for example, at least one of copper or aluminum. The second member 84 includes, for example, at least one of aluminum nitride, silicon nitride, or aluminum oxide. The third member 85 includes, for example, copper. The first adhesive 83a includes, for example, tin. The second adhesive 10a includes, for example, at least one of lead, tin, or silver.

The semiconductor element 10 is, for example, a so-called power semiconductor element such as an IGBT (insulated gate bipolar transistor), a MOSFET (metal-oxide-semiconductor field-effect transistor), etc. The semiconductor element 10 includes, for example, a material such as silicon carbide, gallium nitride, or the like that has a wider bandgap than silicon.

The electrode 20 is located on the semiconductor element 10. The electrode 20 covers at least a portion of the upper surface of the semiconductor element 10. The electrode 20 is electrically connected to the semiconductor element 10. The electrode 20 includes an outer perimeter part 20a and a central part 20b. The outer perimeter part 20a includes an outer perimeter end 20e of the electrode 20. The central part 20b is positioned inward of the outer perimeter part 20a when viewed in plan. The central part 20b is surrounded with the outer perimeter part 20a. That is, the outer perimeter part 20a is positioned at the side of the central part 20b. For example, the central part 20b includes the center of the electrode 20. The wire 86 is located on the central part 20b. The wire 86 is electrically connected to the electrode 20. The wire 86 may be provided as necessary, and is omissible.

The electrode 20 includes, for example, at least one of aluminum or copper. The thickness of the electrode 20 is, for example, not less than 1 μm and not more than 10 μm (e.g., about 4 μm).

The semiconductor module 100 further includes a termination oxide film 60 on the semiconductor element 10. The termination oxide film 60 covers a portion of the upper surface of the semiconductor element 10. The termination oxide film 60 is positioned at the side of the outer perimeter part 20a of the electrode 20. A portion of the termination oxide film 60 is positioned below a portion of the outer perimeter part 20a of the electrode 20. The termination oxide film 60 may be provided as necessary, and is omissible.

The termination oxide film 60 includes, for example, at least one of silicon oxide or silicon nitride. The thickness of the termination oxide film 60 is, for example, not less than 0.1 μm and not more than 5 μm (e.g., about 1.2 μm).

The protective film 30 is located on the electrode 20. The protective film 30 covers at least a portion of the upper surface of the electrode 20. The protective film 30 is located between the electrode 20 and the sealing member 40 (a SiN layer 41 described below). In the semiconductor module 100, the protective film 30 is located at the side of the outer perimeter part 20a and on the outer perimeter part 20a of the electrode 20. The protective film 30 covers at least a portion of the side surface of the outer perimeter part 20a and at least a portion of the upper surface of the outer perimeter part 20a of the electrode 20. In the semiconductor module 100, the protective film 30 covers the entire upper surface of the outer perimeter part 20a. In the semiconductor module 100, the protective film 30 is located on the outer perimeter part 20a and on the termination oxide film 60. The protective film 30 is not located on the central part 20b. That is, the protective film 30 covers at least a portion of the upper surface of the outer perimeter part 20a of the electrode 20, but does not cover the upper surface of the central part 20b. The protective film 30 protects the outer perimeter part 20a of the electrode 20.

The protective film 30 includes, for example, a polyimide resin. The thickness of the protective film 30 is, for example, not less than 1 μm and not more than 10 μm (e.g., about 5 μm). The protective film 30 is provided as necessary, and is omissible.

The sealing member 40 is located on the electrode 20. The sealing member 40 covers at least a portion of the upper surface of the electrode 20. In the semiconductor module 100, the sealing member 40 is located on the protective film 30. The sealing member 40 is located on the central part 20b and on the protective film 30. The sealing member 40 covers at least a portion of the upper surface of the central part 20b and at least a portion of the upper surface of the protective film 30. In the semiconductor module 100, the sealing member 40 covers the entire upper surface of the protective film 30. It is sufficient for the sealing member 40 to cover at least a portion of the upper surface of the protective film 30. In other words, the sealing member 40 may not cover a portion of the upper surface of the protective film 30. When the protective film 30 is not included, the sealing member 40 is located on the electrode 20. For example, the sealing member 40 is located at the side of the outer perimeter part 20a and on the outer perimeter part 20a.

The sealing member 40 includes the SiN layer 41 and a silicone gel layer 42. In the semiconductor module 100, the SiN layer 41 is located on the protective film 30. The SiN layer 41 covers at least a portion of the upper surface of the protective film 30. The silicone gel layer 42 is located on the SiN layer 41. That is, in the semiconductor module 100, the SiN layer 41 is located under the silicone gel layer 42. The silicone gel layer 42 covers at least a portion of the upper surface of the SiN layer 41. The SiN layer 41 contacts the silicone gel layer 42. In the semiconductor module 100, the SiN layer 41 is located at the lowermost part of the sealing member 40.

In the semiconductor module 100, the SiN layer 41 includes a first portion 41a and a second portion 41b. The first portion 41a is located on the protective film 30. The second portion 41b is located at the side of the protective film 30. In the semiconductor module 100, the second portion 41b also is located at the side of the termination oxide film 60.

The SiN layer 41 includes a Si-N-Si bond. The Si-N-Si bond has a structure in which one nitrogen atom (N) is bonded to two silicon atoms (Si). In other words, the Si-N-Si bond has a structure in which one nitrogen atom (N) is positioned between two silicon atoms (Si) in the structural formula. The Si-N-Si bond has, for example, a structure in which the oxygen atom (O) of the siloxane bond (the Si-O-Si bond) is replaced with a nitrogen atom (N). The SiN layer 41 is, for example, a layer formed by using plasma processing to nitride a silicone resin layer including a siloxane bond. The SiN layer 41 includes, for example, a polymer compound having a Si-N-Si bond in the backbone. For example, the SiN layer 41 may have a Si-N bond in a side chain as long as a Si-N-Si bond is in the backbone. The SiN layer 41 may be, for example, a layer formed by chemical vapor deposition (CVD).

Whether or not the SiN layer 41 includes a Si-N-Si bond can be determined by, for example, the position of the bond energy of the nitrogen atom (N) peak as measured by X-ray electron spectroscopy (XPS). For example, in XPS measurements, the 1s peak of the nitrogen atom (N) of a Si-N-Si bond, the 1s peak of the nitrogen atom (N) of a Si-N bond, and the 1s peak of the nitrogen atom (N) of a C-N bond appear at different bond energy positions. Therefore, a Si-N-Si bond can be determined to be present when the 1s peak appears at a prescribed bond energy position; and a Si-N-Si bond can be determined not to be present when the 1s peak does not appear at the prescribed bond energy position.

The SiN layer 41 includes at least a silicon atom (Si) and a nitrogen atom (N). The SiN layer 41 includes, for example, a silicon atom (Si), a nitrogen atom (N), and an oxygen atom (O). The SiN layer 41 includes, for example, a Si-N-Si bond and a siloxane bond (a Si-O-Si bond).

The nitrogen content ratio of the SiN layer 41 relative to Si is, for example, not less than 2 (N/Si ≥ 2) in terms of the elemental composition (atom%) in XPS.

The silicone gel layer 42 includes a silicone gel. The silicone gel includes a siloxane bond (a Si-O-Si bond).

The thickness of the SiN layer 41 is, for example, less than the thickness of the silicone gel layer 42. The thickness of the sealing member 40 is the total value of the thickness of the SiN layer 41 and the thickness of the silicone gel layer 42.

In the semiconductor module 100, the silicone gel layer 42 covers, inside the space surrounded with the frame 82, a portion of the upper surface of the base plate 81, the side surface of the first adhesive 83a, the side surface of the first member 83, a portion of the upper surface of the second member 84, the side surface of the second member 84, a portion of the upper surface of the third member 85, the side surface of the third member 85, the side surface of the second adhesive 10a, a portion of the upper surface of the semiconductor element 10, the side surface of the semiconductor element 10, the side surface of the termination oxide film 60, the side surface of the protective film 30, and the side surface of the SiN layer 41. The wire 86 is located inside the silicone gel layer 42. The sealing member 40 (the silicone gel layer 42) seals the semiconductor element 10.

Effects of the semiconductor module 100 according to the first embodiment will now be described.

When a silicone gel is used as the sealing member 40 in a semiconductor module in which the electrode 20 is located on the semiconductor element 10, moisture that penetrates the sealing member 40 may undesirably reach the electrode 20 and easily cause failure.

In contrast, in the semiconductor module 100, the sealing member 40 includes the SiN layer 41, and so the diffusion of moisture into the sealing member 40 can be suppressed by the SiN layer 41. As a result, moisture that penetrates the sealing member 40 can be prevented from reaching the electrode 20; and failure of the semiconductor module 100 can be suppressed.

In the semiconductor module 100, moisture that penetrates the silicone gel layer 42 can be prevented from reaching the electrode 20 by disposing the SiN layer 41 under the silicone gel layer 42.

In the semiconductor module 100, moisture can be prevented from reaching the electrode 20 by the SiN layer 41 including a silicon atom, a nitrogen atom, and an oxygen atom.

In the semiconductor module 100, the breakdown voltage when a voltage is applied can be increased by including the protective film 30.

In the semiconductor module 100, the outer perimeter part 20a of the electrode 20 can be protected by disposing the protective film 30 at the side of the outer perimeter part 20a and on the outer perimeter part 20a of the electrode 20. By disposing the sealing member 40 on the central part 20b and on the protective film 30, the semiconductor element 10 can be protected from external factors such as heat, moisture, light, etc. The penetration of liquids and gases can be reduced.

In the semiconductor module 100, because the SiN layer 41 includes the first portion 41a located on the protective film 30 and the second portion 41b located at the side of the protective film 30, the penetration of moisture can be suppressed not only from above the protective film 30 but also from the side of the protective film 30.

### Second embodiment

FIG. 4 is a cross-sectional view schematically showing a portion of a semiconductor module according to a second embodiment.

As shown in FIG. 4, the semiconductor module 200 according to the second embodiment is substantially the same as the semiconductor module 100 according to the first embodiment, other than the position of the SiN layer 41 being different.

In the semiconductor module 200, the SiN layer 41 is located inside the silicone gel layer 42. The silicone gel layer 42 includes a first region 42a and a second region 42b. The first region 42a is positioned under the SiN layer 41. The second region 42b is positioned on the SiN layer 41. In the semiconductor module 200, the first region 42a is located on the protective film 30; the SiN layer 41 is located on the first region 42a; and the second region 42b is located on the SiN layer 41. In the semiconductor module 200, the first region 42a covers at least a portion of the upper surface of the protective film 30; the SiN layer 41 covers at least a portion of the upper surface of the first region 42a; and the second region 42b covers at least a portion of the upper surface of the SiN layer 41.

For example, the thickness of the first region 42a may be less than the thickness of the second region 42b, greater than the thickness of the second region 42b, or equal to the thickness of the second region 42b.

Effects similar to those of the semiconductor module 100 can be obtained in the semiconductor module 200 as well.

In the semiconductor module 200, moisture that penetrates the silicone gel layer 42 (the second region 42b) can be prevented from reaching the electrode 20 by disposing the SiN layer 41 inside the silicone gel layer 42.

### Third embodiment

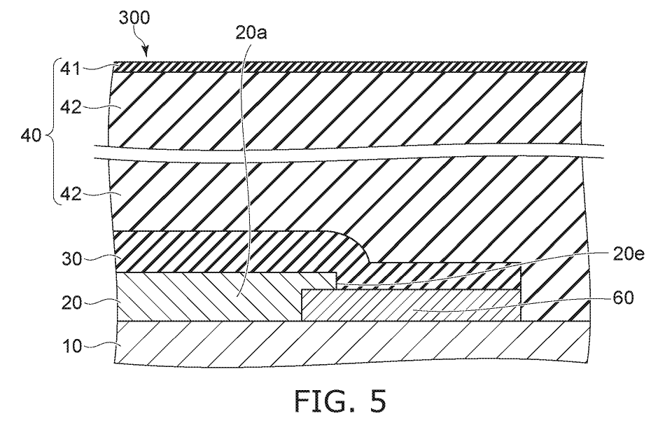

FIG. 5 is a cross-sectional view schematically showing a portion of a semiconductor module according to a third embodiment.

As shown in FIG. 5, the semiconductor module 300 according to the third embodiment is substantially the same as the semiconductor module 100 according to the first embodiment, other than the position of the SiN layer 41 being different.

In the semiconductor module 300, the SiN layer 41 is located on the silicone gel layer 42. In the semiconductor module 300, the silicone gel layer 42 is located on the protective film 30; and the SiN layer 41 is located on the silicone gel layer 42. In the semiconductor module 300, the SiN layer 41 is located at the uppermost part of the sealing member 40. In the semiconductor module 300, the silicone gel layer 42 covers at least a portion of the upper surface of the protective film 30; and the SiN layer 41 covers at least a portion of the upper surface of the silicone gel layer 42.

Effects similar to those of the semiconductor module 100 can be obtained for the semiconductor module 300 as well.

In the semiconductor module 300, penetration of moisture into the silicone gel layer 42 can be suppressed by disposing the SiN layer 41 on the silicone gel layer 42.

Although an example is described in the first to third embodiments above in which the sealing member 40 includes one SiN layer 41, the sealing member 40 may include two or more SiN layers 41. In such a case, the silicone gel layer 42 is located between the two SiN layers 41. For example, the SiN layers 41 may be located under the silicone gel layer 42 and inside the silicone gel layer 42; under the silicone gel layer 42 and on the silicone gel layer 42; inside the silicone gel layer 42 and on the silicone gel layer 42; or under the silicone gel layer 42, inside the silicone gel layer 42, and on the silicone gel layer 42.

### Method for manufacturing semiconductor module

### First embodiment

FIGS. 6A to 6E are cross-sectional views schematically showing a method for manufacturing the semiconductor module according to the first embodiment.

As shown in FIGS. 6A to 6E, the method for manufacturing the semiconductor module according to the first embodiment includes a first process and a second process. FIG. 6A illustrates the first process. FIGS. 6B to 6E illustrate the second process.

In the first process as shown in FIG. 6A, the electrode 20 is formed on the semiconductor element 10. The electrode 20 is electrically connected to the semiconductor element 10. The electrode 20 includes the outer perimeter part 20a and the central part 20b (see FIG. 2). In the example of FIG. 6A, the termination oxide film 60 also is formed on the semiconductor element 10. More specifically, first, the termination oxide film 60 is formed on the semiconductor element 10, and then the electrode 20 is formed so that a portion (the outer perimeter part 20a) of the electrode 20 overlaps the termination oxide film 60. The termination oxide film 60 may be provided as necessary, and is omissible.

In the second process as shown in FIGS. 6B to 6E, the SiN layer 41 that includes a Si-N-Si bond and the sealing member 40 that includes the silicone gel layer 42 including a silicone gel is formed on the electrode 20. The sealing member 40 is formed to cover at least a portion of the upper surface of the electrode 20.

In the second process, first, as shown in FIG. 6B, the protective film 30 is formed at the side of the outer perimeter part 20a and on the outer perimeter part 20a of the electrode 20. The protective film 30 is formed to cover at least a portion of the side surface of the outer perimeter part 20a of the electrode 20 and at least a portion of the upper surface of the outer perimeter part 20a. As described above, the protective film 30 includes a polyimide resin. In the example of FIG. 6B, the protective film 30 is formed on the outer perimeter part 20a and on the termination oxide film 60. For example, the protective film 30 can be formed by coating a material including a polyimide resin at the side of the outer perimeter part 20a and on the outer perimeter part 20a of the electrode 20. When the protective film 30 is not included, the process of FIG. 6B may be omitted.

Then, in the second process as shown in FIG. 6C, a silicone resin layer 45 that includes a siloxane bond is formed on the protective film 30. The silicone resin layer 45 is formed to cover at least a portion of the upper surface of the protective film 30. At this time, for example, the silicone resin layer 45 is formed to include a first portion 45a formed on the protective film 30 and a second portion 45b formed at the side of the protective film 30. The silicone resin layer 45 may be formed from the same material as the silicone gel layer 42, or may be formed from a different material from the silicone gel layer 42.

Then, in the second process as shown in FIG. 6D, the SiN layer 41 is formed by nitriding the silicone resin layer 45 by plasma processing. The plasma processing replaces the oxygen atom (O) of the siloxane bond (the Si-O-Si bond) of the silicone resin layer 45 with a nitrogen atom (N) to form the SiN layer 41 including a Si-N-Si bond. The first portion 45a of the silicone resin layer 45 becomes the first portion 41a of the SiN layer 41. The second portion 45b of the silicone resin layer 45 becomes the second portion 41b of the SiN layer 41. At this time, only a portion (e.g., the surface) of the silicone resin layer 45 may be used to form the SiN layer 41, or the entire silicone resin layer 45 may be used to form the SiN layer 41. For example, the plasma processing is performed using a gas including N₂ and/or NH₃ under the conditions of atmospheric pressure plasma or low-temperature plasma under vacuum. For example, the replacement ratio of oxygen atoms to nitrogen atoms (i.e., the nitrogen content ratio of the SiN layer 41) can be set to the desired value by modifying the conditions of the plasma processing.

Then, in the second process as shown in FIG. 6E, the silicone gel layer 42 is formed on the central part 20b of the electrode 20 and on the SiN layer 41. The silicone gel layer 42 is formed to cover at least a portion of the upper surface of the central part 20b of the electrode 20 and at least a portion of the upper surface of the SiN layer 41. For example, the silicone gel layer 42 can be formed by coating a material including a silicone gel on the central part 20b of the electrode 20, on the SiN layer 41, and on the semiconductor element 10.

Thus, the semiconductor module 100 according to the first embodiment can be manufactured by the first process shown in FIG. 6A and the second process shown in FIGS. 6B to 6E.

### Modification of first embodiment

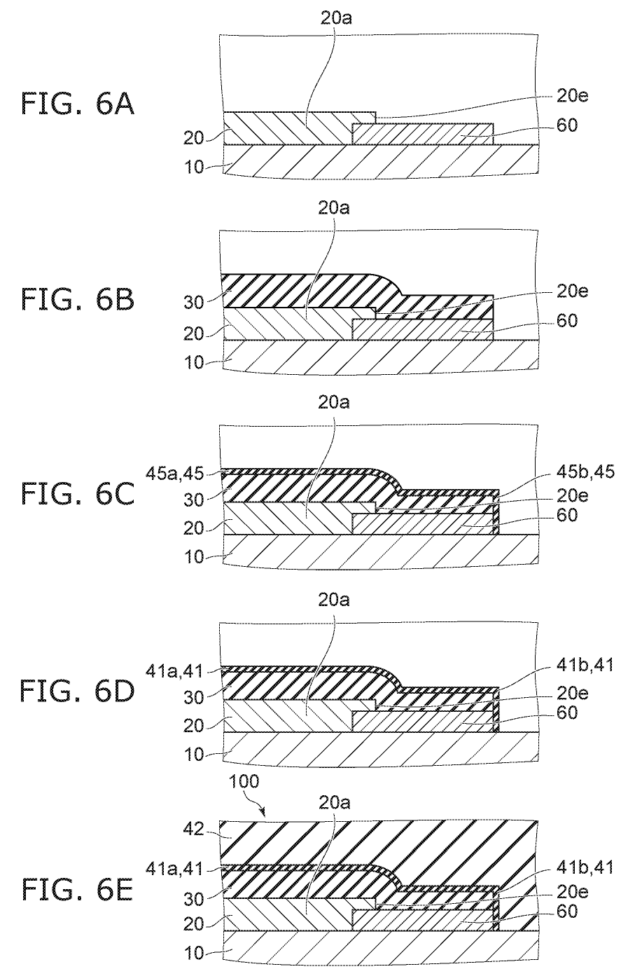

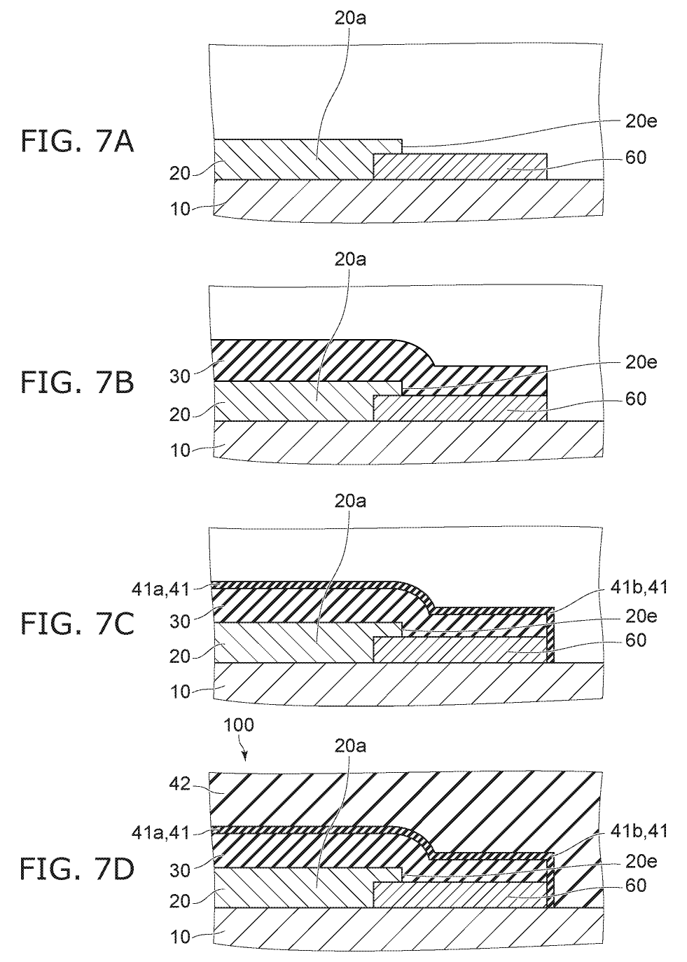

FIGS. 7A to 7D are cross-sectional views schematically showing a modification of the method for manufacturing the semiconductor module according to the first embodiment.

As shown in FIGS. 7A to 7D, the modification of the method for manufacturing the semiconductor module according to the first embodiment is the same as the method for manufacturing the semiconductor module according to the first embodiment shown in FIGS. 6A to 6E, other than the method for forming the SiN layer 41 in the second process is different. FIG. 7A illustrates the first process. FIGS. 7B to 7D illustrate the second process.

According to the modification of the method for manufacturing the semiconductor module according to the first embodiment, the process of FIG. 7C is performed instead of the processes of FIGS. 6C and 6D. The processes of FIGS. 7A, 7B, and 7D are substantially the same as the processes of FIGS. 6A, 6B, and 6E; and a description is therefore omitted.

According to the modification of the method for manufacturing the semiconductor module according to the first embodiment as shown in FIG. 7C of the second process, the SiN layer 41 is formed by chemical vapor deposition (CVD) on the protective film 30 and at the side of the protective film 30. For example, CVD is performed by plasma CVD using a gas such as N₂, NH₃, N₂O, SiH₄, H₂, etc. For example, the nitrogen content ratio of the SiN layer 41 can be set to the desired value by modifying the CVD conditions.

Thus, the semiconductor module 100 according to the first embodiment can be manufactured by the first process shown in FIG. 7A and the second process shown in FIGS. 7B to 7D.

### Second embodiment

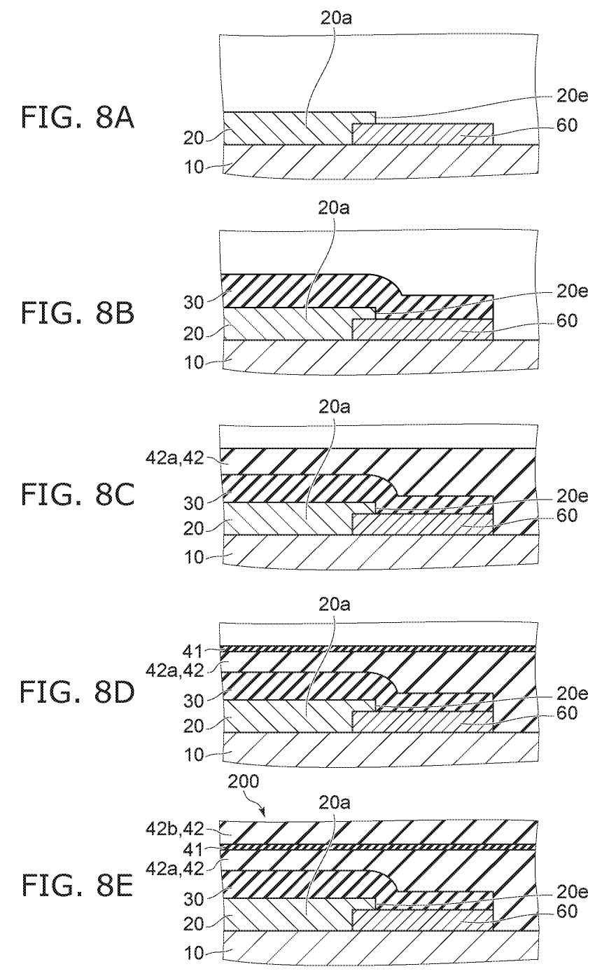

FIGS. 8A to 8E are cross-sectional views schematically showing a method for manufacturing the semiconductor module according to the second embodiment.

As shown in FIGS. 8A to 8E, the method for manufacturing the semiconductor module according to the second embodiment is substantially the same as the method for manufacturing the semiconductor module according to the first embodiment, other than the second process being different. FIG. 8A illustrates the first process. FIGS. 8B to 8E illustrate the second process.

According to the method for manufacturing the semiconductor module according to the second embodiment, the processes of FIGS. 8C to 8E are performed instead of the processes of FIGS. 6C to 6E. The processes of FIGS. 8A and 8B are substantially the same as the processes of FIGS. 6A and 6B; and a description is therefore omitted.

According to the method for manufacturing the semiconductor module according to the second embodiment as shown in FIG. 8C of the second process, a portion (the first region 42a) of the silicone gel layer 42 is formed on the central part 20b of the electrode 20 and on the protective film 30. The portion (the first region 42a) of the silicone gel layer 42 is formed to cover at least a portion of the upper surface of the central part 20b of the electrode 20 and at least a portion of the upper surface of the protective film 30. For example, the first region 42a of the silicone gel layer 42 can be formed by coating a material including a silicone gel on the central part 20b of the electrode 20, on the protective film 30, and on the semiconductor element 10.

Then, according to the method for manufacturing the semiconductor module according to the second embodiment as shown in FIG. 8D of the second process, the SiN layer 41 is formed on the first region 42a of the silicone gel layer 42 by nitriding a portion of the first region 42a of the silicone gel layer 42 by plasma processing. The SiN layer 41 is formed to cover at least a portion of the upper surface of the first region 42a of the silicone gel layer 42. The plasma processing replaces the oxygen atom (O) of the siloxane bond (the Si-O-Si bond) of the first region 42a of the silicone gel layer 42 with a nitrogen atom (N) to form the SiN layer 41 including a Si-N-Si bond. For example, the conditions of the plasma processing may be the same as the conditions described above.

Then, according to the method for manufacturing the semiconductor module according to the second embodiment as shown in FIG. 8E of the second process, another portion (the second region 42b) of the silicone gel layer 42 is formed on the SiN layer 41. The other portion (the second region 42b) of the silicone gel layer 42 is formed to cover at least a portion of the upper surface of the SiN layer 41. For example, the second region 42b of the silicone gel layer 42 can be formed by coating a material including a silicone gel on the SiN layer 41.

Thus, the semiconductor module 200 according to the second embodiment can be manufactured by the first process shown in FIG. 8A and the second process shown in FIGS. 8B to 8E.

### Modification of second embodiment

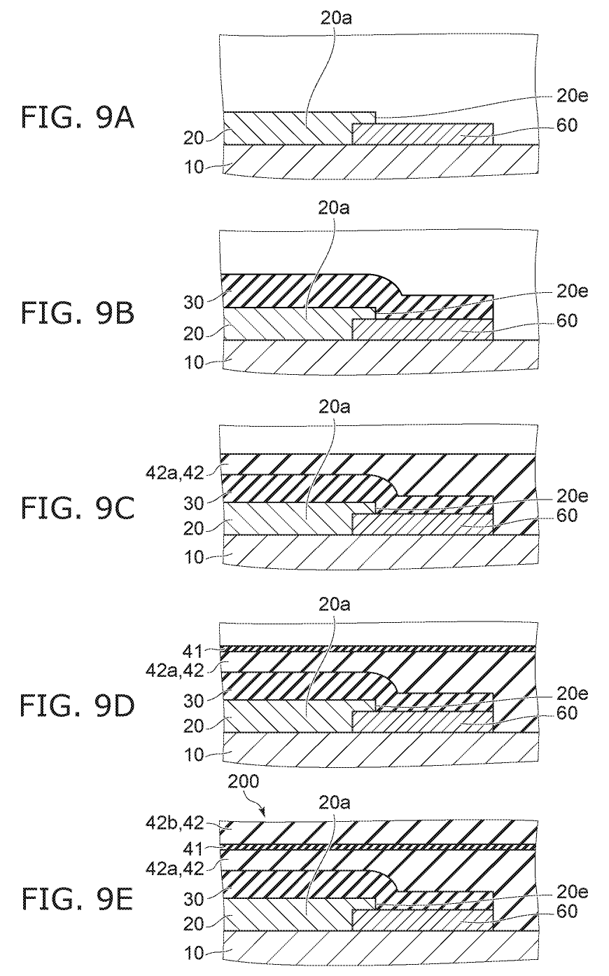

FIGS. 9A to 9E are cross-sectional views schematically showing a modification of the method for manufacturing the semiconductor module according to the second embodiment.

As shown in FIGS. 9A to 9E, the modification of the method for manufacturing the semiconductor module according to the second embodiment is the same as the method for manufacturing the semiconductor module according to the second embodiment shown in FIGS. 8A to 8E, other than the method for forming the SiN layer 41 in the second process being different. FIG. 9A illustrates the first process. FIGS. 9B to 9E illustrate the second process.

According to the modification of the method for manufacturing the semiconductor module according to the second embodiment, the process of FIG. 9D is performed instead of the process of FIG. 8D. The processes of FIGS. 9A to 9C and 9E are substantially the same as the processes of FIGS. 8A to 8C and 8E; and a description is therefore omitted.

According to the modification of the method for manufacturing the semiconductor module according to the second embodiment as shown in FIG. 9D of the second process, the SiN layer 41 is formed by chemical vapor deposition (CVD) on the first region 42a of the silicone gel layer 42. For example, the CVD conditions may be the same as the conditions described above. The SiN layer 41 is formed to cover at least a portion of the upper surface of the first region 42a of the silicone gel layer 42.

Thus, the semiconductor module 200 according to the second embodiment can be manufactured by the first process shown in FIG. 9A and the second process shown in FIGS. 9B to 9E.

### Third embodiment

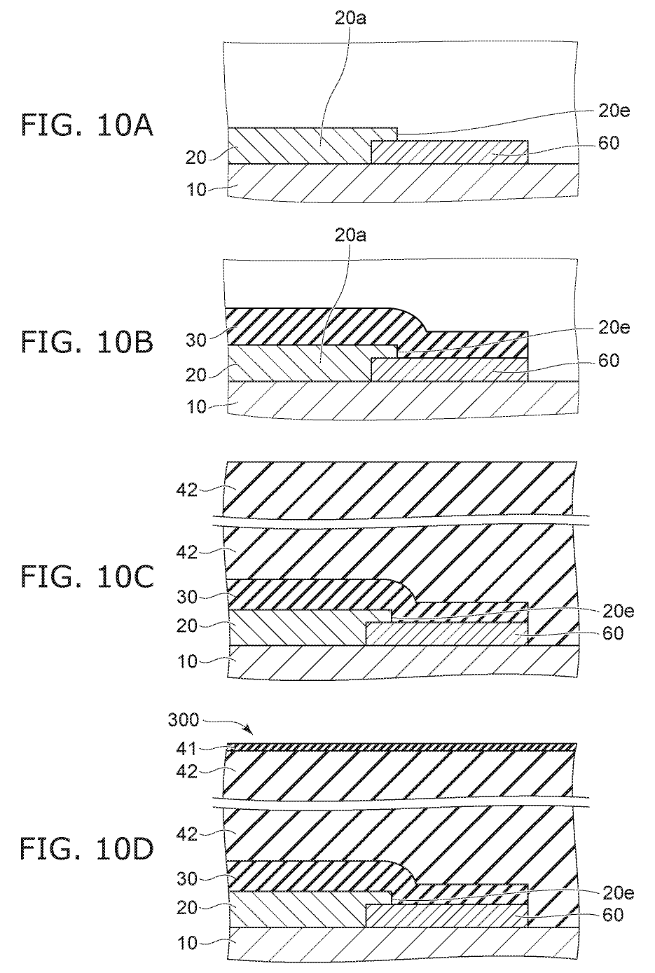

FIGS. 10A to 10D are cross-sectional views schematically showing a method for manufacturing the semiconductor module according to the third embodiment.

As shown in FIGS. 10A to 10D, the method for manufacturing the semiconductor module according to the third embodiment is substantially the same as the method for manufacturing the semiconductor module according to the first embodiment, other than the second process being different. FIG. 10A illustrates the first process. FIGS. 10B to 10D illustrate the second process.

According to the method for manufacturing the semiconductor module according to the third embodiment, the processes of FIGS. 10C and 10D are performed instead of the processes of FIGS. 6C to 6E. The processes of FIGS. 10A and 10B are substantially the same as the processes of FIGS. 6A and 6B; and a description is therefore omitted.

According to the method for manufacturing the semiconductor module according to the third embodiment as shown in FIG. 10C of the second process, the silicone gel layer 42 is formed on the central part 20b of the electrode 20 and on the protective film 30. The silicone gel layer 42 is formed to cover at least a portion of the upper surface of the central part 20b of the electrode 20 and at least a portion of the upper surface of the protective film 30. For example, the silicone gel layer 42 can be formed by coating a material including a silicone gel on the central part 20b of the electrode 20, on the protective film 30, and on the semiconductor element 10.

Then, according to the method for manufacturing the semiconductor module according to the third embodiment as shown in FIG. 10D of the second process, the SiN layer 41 is formed on the silicone gel layer 42 by nitriding a portion of the silicone gel layer 42 by plasma processing. The SiN layer 41 is formed to cover at least a portion of the upper surface of the silicone gel layer 42. The plasma processing replaces the oxygen atom (O) of the siloxane bond (the Si-O-Si bond) of the silicone gel layer 42 with a nitrogen atom (N) to form the SiN layer 41 including a Si-N-Si bond. For example, the conditions of the plasma processing may be the same as the conditions described above.

Thus, the semiconductor module 300 according to the third embodiment can be manufactured by the first process shown in FIG. 10A and the second process shown in FIGS. 10B to 10D.

### Modification of third embodiment

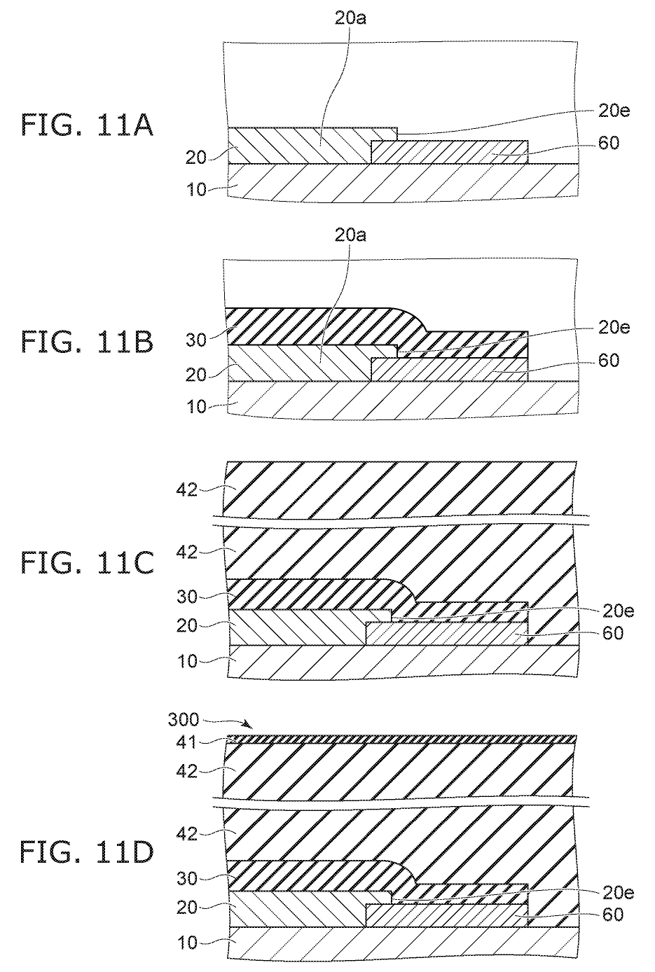

FIGS. 11A to 11D are cross-sectional views schematically showing a modification of the method for manufacturing the semiconductor module according to the third embodiment.

As shown in FIGS. 11A to 11D, the modification of the method for manufacturing the semiconductor module according to the third embodiment is the same as the method for manufacturing the semiconductor module according to the third embodiment shown in FIGS. 10A to 10D, other than the method for forming the SiN layer 41 in the second process being different. FIG. 11A illustrates the first process. FIGS. 11B to 11D illustrate the second process.

According to the modification of the method for manufacturing the semiconductor module according to the third embodiment, the process of FIG. 11D is performed instead of the process of FIG. 10D. The processes of FIGS. 11A to 11C are substantially the same as the processes of FIGS. 10A to 10C; and a description is therefore omitted.

According to the modification of the method for manufacturing the semiconductor module according to the third embodiment as shown in FIG. 11D of the second process, the SiN layer 41 is formed by chemical vapor deposition (CVD) on the silicone gel layer 42. The SiN layer 41 is formed to cover at least a portion of the upper surface of the silicone gel layer 42. For example, the CVD conditions may be the same as the conditions described above.

Thus, the semiconductor module 300 according to the third embodiment can be manufactured by the first process shown in FIG. 11A and the second process shown in FIGS. 11B to 11D.

Embodiments may include the following configurations.

### Configuration 1

A semiconductor module, comprising:

a semiconductor element;

an electrode electrically connected to the semiconductor element; and

a sealing member covering at least a portion of the electrode,

the sealing member including

a SiN layer including a Si-N-Si bond, and

a silicone gel layer including a silicone gel.

### Configuration 2

The semiconductor module according to Configuration 1, wherein

the SiN layer includes a silicon atom, a nitrogen atom, and an oxygen atom.

### Configuration 3

The semiconductor module according to Configuration 1 or 2, wherein

the silicone gel layer covers at least a portion of the SiN layer.

### Configuration 4

The semiconductor module according to Configuration 3, wherein

the SiN layer contacts the silicone gel layer.

### Configuration 5

The semiconductor module according to any one of Configurations 1 to 4, wherein

the SiN layer is located inside the silicone gel layer.

### Configuration 6

The semiconductor module according to any one of Configurations 1 to 5, wherein

the SiN layer covers at least a portion of the silicone gel layer.

### Configuration 7

The semiconductor module according to any one of Configurations 1 to 6, further comprising:

a protective film located between the electrode and the SiN layer,

the protective film including a polyimide resin,

the sealing member covering at least a portion of the protective film.

### Configuration 8

The semiconductor module according to Configuration 7, wherein

the electrode includes:

an outer perimeter part including an outer perimeter end; and

a central part positioned inward of the outer perimeter part when viewed in plan,

the protective film covers at least a portion of a side surface of the outer perimeter part and at least a portion of an upper surface of the outer perimeter part, and

the sealing member covers at least a portion of the central part and at least a portion of the protective film.

### Configuration 9

The semiconductor module according to Configuration 7 or 8, wherein

the SiN layer includes:

a first portion covering at least a portion of an upper surface of the protective film; and

a second portion covering at least a portion of a side surface of the protective film.

### Configuration 10

A method for manufacturing a semiconductor module, the method comprising:

a first process of forming an electrode electrically connected to a semiconductor element; and

a second process of forming a sealing member to cover at least a portion of the electrode,

the sealing member including

a SiN layer including a Si-N-Si bond, and

a silicone gel layer including a silicone gel.

### Configuration 11

The method for manufacturing the semiconductor module according to Configuration 10, wherein

the second process includes forming the SiN layer by:

forming a silicone resin layer including a siloxane bond; and

nitriding the silicone resin layer by plasma processing.

### Configuration 12

The method for manufacturing the semiconductor module according to Configuration 10, wherein

the second process includes forming the SiN layer by chemical vapor deposition.

### Configuration 13

The method for manufacturing the semiconductor module according to any one of Configurations 10 to 12, wherein

the second process includes:

forming the SiN layer to cover at least a portion of the electrode; and

forming the silicone gel layer to cover at least a portion of the SiN layer.

### Configuration 14

The method for manufacturing the semiconductor module according to any one of Configurations 10 to 13, wherein

the second process includes:

forming the silicone gel layer so that a portion of the silicone gel layer covers at least a portion of the electrode;

forming the SiN layer to cover a portion of the silicone gel layer; and

forming the silicone gel layer so that another portion of the silicone gel layer covers at least a portion of the SiN layer.

### Configuration 15

The method for manufacturing the semiconductor module according to any one of Configurations 10 to 14, wherein

the second process includes:

forming the silicone gel layer to cover at least a portion of the electrode; and

forming the SiN layer to cover at least a portion of the silicone gel layer.

### Configuration 16

The method for manufacturing the semiconductor module according to any one of Configurations 10 to 15, wherein

the second process includes:

forming a protective film to cover at least a portion of the electrode, the protective film including a polyimide resin; and

forming the sealing member to cover at least a portion of the protective film.

### Configuration 17

The method for manufacturing the semiconductor module according to Configuration 16, wherein

the first process includes forming the electrode to be electrically connected to the semiconductor element so that the electrode includes:

an outer perimeter part including an outer perimeter end; and

a central part positioned inward of the outer perimeter part when viewed in plan, and

the second process includes:

forming the protective film to cover at least a portion of a side surface of the outer perimeter part and at least a portion of an upper surface of the outer perimeter part; and

forming the sealing member to cover at least a portion of the central part and at least a portion of the protective film.

Thus, according to embodiments, a semiconductor module and a method for manufacturing a semiconductor module can be provided in which moisture that penetrates the sealing member can be prevented from reaching the electrode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor module, comprising:
a semiconductor element;
an electrode electrically connected to the semiconductor element; and
a sealing member covering at least a portion of the electrode,
the sealing member including
a SiN layer including a Si-N-Si bond, and
a silicone gel layer including a silicone gel.

2. The semiconductor module according to claim 1, wherein
the SiN layer includes a silicon atom, a nitrogen atom, and an oxygen atom.

3. The semiconductor module according to claim 1, wherein
the silicone gel layer covers at least a portion of the SiN layer.

4. The semiconductor module according to claim 3, wherein
the SiN layer contacts the silicone gel layer.

5. The semiconductor module according to claim 1, further comprising:
a protective film located between the electrode and the SiN layer,
the protective film including a polyimide resin,
the sealing member covering at least a portion of the protective film.

6. The semiconductor module according to claim 5, wherein
the electrode includes:
an outer perimeter part including an outer perimeter end; and
a central part positioned inward of the outer perimeter part when viewed in plan,
the protective film covers at least a portion of a side surface of the outer perimeter part and at least a portion of an upper surface of the outer perimeter part, and
the sealing member covers at least a portion of the central part and at least a portion of the protective film.

7. The semiconductor module according to claim 5, wherein
the SiN layer includes:
a first portion covering at least a portion of an upper surface of the protective film; and
a second portion covering at least a portion of a side surface of the protective film.

8. A method for manufacturing a semiconductor module, the method comprising:
a first process of forming an electrode electrically connected to a semiconductor element; and
a second process of forming a sealing member to cover at least a portion of the electrode,
the sealing member including
a SiN layer including a Si-N-Si bond, and
a silicone gel layer including a silicone gel.

9. The method according to claim 8, wherein
the second process includes forming the SiN layer by:
forming a silicone resin layer including a siloxane bond; and
nitriding the silicone resin layer by plasma processing.

10. The method according to claim 8, wherein
the second process includes:
forming the SiN layer to cover at least a portion of the electrode; and
forming the silicone gel layer to cover at least a portion of the SiN layer.

11. The method according to claim 8, wherein
the second process includes:
forming a protective film to cover at least a portion of the electrode, the protective film including a polyimide resin; and
forming the sealing member to cover at least a portion of the protective film.

12. The method according to claim 11, wherein
the first process includes forming the electrode to be electrically connected to the semiconductor element so that the electrode includes:
an outer perimeter part including an outer perimeter end; and
a central part positioned inward of the outer perimeter part when viewed in plan, and
the second process includes:
forming the protective film to cover at least a portion of a side surface of the outer perimeter part and at least a portion of an upper surface of the outer perimeter part; and
forming the sealing member to cover at least a portion of the central part and at least a portion of the protective film.
